(19) United States
(12) Patent Application Publication
(10) Pub. No.: US 2023/0062455 A1
(43) Pub. Date: Mar. 2, 2023

(54) VAPORIZER ASSEMBLY

(71) Applicant: ENTEGRIS, INC., Billerica, MA (US)

(72) Inventors: Benjamin Cardozo, Burnet, TX (US); Scott L. Battle, Cedar Park, TX (US)

(21) Appl. No.: 17/900,713

(22) Filed: Aug. 31, 2022

Related U.S. Application Data
(60) Provisional application No. 63/239,631, filed on Sep. 1, 2021.

(51) Int. Cl. C23C 16/48

(52) U.S. Cl. CPC C23C 16/481

(57) ABSTRACT

An assembly includes a vaporizer vessel. In some embodiments, the vaporizer vessel defines an interior volume. In some embodiments, the vaporizer vessel is configured to hold at least one source reagent within the interior volume. In some embodiments, the assembly includes a heater. In some embodiments, the heater is configured to vaporize the at least one source reagent. In some embodiments, the heater is a radiant heat source configured to vaporize the at least one source reagent without heating the vaporizer vessel.

### PRIORITY CLAIM

This disclosure claims priority to U.S. Provisional Patent No. 63/239,631, with a filing date of Sep. 1, 2021 which is incorporated by reference herein.

### FIELD

This disclosure relates generally to a vaporizer. More particularly, this disclosure relates to a vaporizer for vaporization of source reagent materials used in, for example, chemical vapor deposition (CVD) and atomic layer deposition (ALD) processes

### BACKGROUND

Vaporizers for solid precursors generally leverage conductive heating from metallic vessel surfaces to the solid precursor. To disperse heat through the solid precursor, an internal metallic structure can be utilized to provide metallic thermal pathways for the heating.

### SUMMARY

In some embodiments, an assembly includes a vaporizer vessel. In some embodiments, the vaporizer vessel defines an interior volume. In some embodiments, the vaporizer vessel is configured to hold at least one source reagent within the interior volume. In some embodiments, a heater is disposed within the interior volume of the vaporizer vessel. In some embodiments, the heater is disposed within the interior volume of the vaporizer vessel in an arrangement such that the at least one source reagent is vaporized by direct heating.

In some embodiments, the heater is a radiant heat source.

In some embodiments, the heater is configured to provide radiant energy to the interior volume of the vaporizer vessel at a wavelength sufficient to vaporize the at least one source reagent.

In some embodiments, radiant energy from the heater is directed to the at least one source reagent, without passing through a solid medium, to vaporize the at least one source reagent.

In some embodiments, the assembly includes a second heater configured to heat the vaporizer vessel. In some embodiments, the second heater is disposed outside the vaporizer vessel.

In some embodiments, an assembly includes a vaporizer vessel. In some embodiments, the vaporizer vessel defines an interior volume and includes a transparent viewport. In some embodiments, the vaporizer vessel is configured to hold at least one source reagent within the interior volume. In some embodiments, a heater is disposed outside the vaporizer vessel. In some embodiments, the heater is disposed outside the vaporizer vessel in an arrangement such that the at least one source reagent is vaporized by heating the at least one source reagent through the transparent viewport.

In some embodiments, the heater is a radiant heat source.

In some embodiments, the heater is configured to provide radiant energy to the interior volume of the vaporizer vessel at a wavelength sufficient to vaporize the at least one source reagent.

In some embodiments, radiant energy from the heater is directed to the at least one source reagent, without passing through a solid medium, to vaporize the at least one source reagent.

In some embodiments, the assembly includes a second heater configured to heat the vaporizer vessel. In some embodiments, the second heater is disposed outside the vaporizer vessel.

In some embodiments, an assembly includes a vaporizer vessel. In some embodiments, the vaporizer vessel defines an interior volume. In some embodiments, the vaporizer vessel is configured to hold at least one source reagent within the interior volume. In some embodiments, the assembly includes a heater. In some embodiments, the heater is a directional radiant heat source configured to vaporize the at least one source reagent by direct radiant heating to a greater extent than the at least one source reagent is vaporized by conductive heating. In some embodiments, the heater is configured to vaporize the at least one source reagent without heating the vaporizer vessel.

In some embodiments, the radiant heat source directly heats the at least one source reagent.

In some embodiments, the heater is disposed within the interior volume of the vaporizer vessel.

In some embodiments, radiant energy from the heater is directed to the at least one source reagent, without passing through a solid medium, to vaporize the at least one source reagent.

In some embodiments, the assembly includes a transparent viewport.

In some embodiments, the heater is disposed outside the vaporizer vessel.

In some embodiments, radiant energy from the heater is directed through the transparent viewport to the at least one source reagent to vaporize the at least one source reagent.

In some embodiments, the heater is configured to provide radiant energy to the interior volume of the vaporizer vessel at a wavelength sufficient to vaporize the at least one source reagent.

In some embodiments, the assembly includes a second heater. In some embodiments, the second heater is configured to heat the vaporizer vessel.

In some embodiments, the assembly includes the at least one source reagent.

### BRIEF DESCRIPTION OF THE DRAWINGS

References are made to the accompanying drawings that form a part of this disclosure and that illustrate embodiments in which the systems and methods described in this Specification can be practiced.

FIG. 1 is a schematic diagram of a vaporizer assembly, according to some embodiments.

FIG. 2 is a schematic diagram of a vaporizer assembly, according to some embodiments.

FIG. 3 is a flowchart of a method for controlling a vaporizer assembly, according to some embodiments.

Like reference numbers represent the same or similar parts throughout.

### DETAILED DESCRIPTION

Vaporizers for solid precursors generally leverage conductive heating from metallic vessel surfaces to the solid precursor itself. To disperse heat through the solid precursor, an internal metallic structure can be utilized to provide metallic thermal pathways for the heating. Conductive heating is limited due to controllability and response times of the heating process. For example, controllability may be limited due to high thermal mass and low conductivity of the conductive thermal pathways. For example, when a heater is turned off, the thermal pathway may still provide heat before beginning to cool. Additionally, conductive heating can have a higher cost due to heat transfer losses from the heater to the thermal pathways. In some cases, performance may be limited due to corrosion and contamination effects over time.

Embodiments of this disclosure relate to a vaporizer, systems, and methods for volatilization of source reagents to produce vapor for fluid-utilizing processes such as chemical vapor deposition or ion implantation.

Embodiments of this disclosure can be applied with various types of source reagents, including solid form source reagent materials, liquid form source reagent materials, semi-solid from source reagent materials, slurry form source reagent materials (including solid materials suspended in a liquid), and solutions of solid materials dissolved in a solvent. In some embodiments, solid form source reagent materials may, for example, be in the form of powders, granules, pellets, beads, bricks, blocks, sheets, rods, plates, films, coatings, or the like, and may embody porous or nonporous forms, as desirable in a given application.

Embodiments of this disclosure can provide a heater for directly heating the source reagent without heating the vaporizer vessel. As used herein, “without heating the vaporizer vessel” or “direct radiant heating” include directing a heater to provide heat to the source reagent without passing through a solid medium, instead of directing a heater to the vaporizer vessel to conductively heat the source reagent. As directing the heater to provide heat to the source reagent may increase a temperature of the vaporizer vessel, the term “without heating the vaporizer vessel” permits indirect heating of the vaporizer vessel as a result of heating the source reagent. “Direct radiant heating” or “without heating the vaporizer vessel” include radiant heating with a heater inside a vessel or radiant heating with a heater outside the vessel that is directed at the source reagent through a transparent viewport.

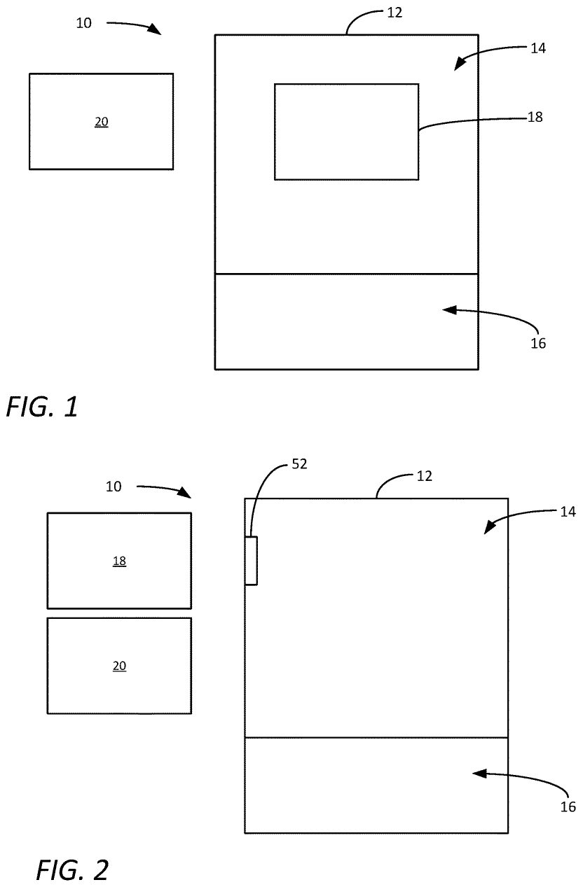

FIG. 1 is a schematic diagram of a vaporizer assembly 10, according to some embodiments. The vaporizer assembly 10 can be used to deliver a vaporized source reagent in, for example, chemical vapor deposition (CVD) and atomic layer deposition (ALD) processes. It is to be appreciated that these applications are examples and that additional uses for the vaporizer assembly 10 are possible within the scope of the present disclosure.

The vaporizer assembly 10 includes a vaporizer vessel 12. The vaporizer vessel 12 includes an interior volume 14. The interior volume 14 holds a source reagent 16. A heater 18 is included to heat the source reagent 16. The source reagent 16 as heated can be provided via an outlet from the vaporizer vessel 12 as a vaporized source reagent.

In some embodiments, the vaporizer vessel 12 is formed of a heat-conducting material. In some embodiments, the heat-conducting material can be, but is not limited to, silver, silver alloy, copper, copper alloy, aluminum, aluminum alloy, lead, nickel clad, stainless steel, graphite, silicon carbide coated graphite, boron nitride, ceramic material, any combination thereof, or the like. In an embodiment, the vaporizer vessel 12 may comprise a coating. A coating may be selected to enhance chemical inertness of the vaporizer vessel 12. In an example, the coating may comprise an aluminum oxide, silicon dioxide, or yttrium oxide. The vaporizer vessel 12 may include a passivation treatment. The passivation treatment may be, for example, a fluorine passivation. The vaporizer vessel 12 can have any shape. In some embodiments, the vaporizer vessel 12 can be cylindrical in shape.

It is to be appreciated that the vaporizer vessel 12 can include additional elements such as, but not limited to, a carrier gas inlet for providing a gas that will support the vaporized source reagent and an outlet for the vaporized source reagent.

One or more additional structures can be included for the purpose of holding the source reagent 16 in the interior volume 14. In some embodiments, one or more structures can be present to hold the heater 18 in a location which directs the heater 18 at the source reagent 16. In some embodiments, one or more structures can be present to direct heat toward the source reagent 16. Such structures can be, for example, a thermally reflective material or the like. In some embodiments, a thermally absorbent material can be included in the interior volume 14 to prevent heat from the heater 18 being provided to unintended areas of the interior volume 14. In some embodiments, the interior volume 14 can include a thermally absorbent material that is in contact with the source reagent 16 to provide conductive heat to the source reagent 16 in addition to the radiant heat.

In some embodiments, the vaporizer assembly 10 can additionally include lines for supplying a carrier gas to the vaporizer vessel 12; lines for discharging source reagent 16 vapor from the vaporizer vessel 12; flow circuitry components such as flow control valves, mass flow controllers, regulators, restricted flow orifice elements, thermocouples, pressure transducers, monitoring and control devices, heaters for input of thermal energy to the vaporizer vessel and its contents, heaters for maintaining temperature in the carrier gas supply lines and source reagent vapor discharge lines, any combination thereof, or the like.

The source reagent 16 can include solid precursors of any suitable type. Examples of such solid precursors include, but are not limited to, solid-phase metal halides, organometallic solids, any combination thereof, or the like. Examples of the source reagent 16 that may be utilized include, but are not limited to, dimethyl hydrazine, trimethyl aluminum (TMA), hafnium chloride (HfCl₄), zirconium chloride (ZrCl₄), indium trichloride, aluminum trichloride, titanium iodide, tungsten carbonyl, Ba(DPM)₂, bis di pivaloyl methanato strontium (Sr(DPM)₂), TiO(DPM)₂, tetra di pivaloyl methanato zirconium (Zr(DPM)₄), decaborane, boron, magnesium, gallium, indium, antimony, copper, phosphorous, arsenic, lithium, sodium tetrafluoroborates, precursors incorporating alkyl-amidinate ligands, organometallic precursors, zirconium tertiary butoxide (Zr (t-OBu)₄), tetrakisdiethylaminozirconium (Zr(Net₂)₄), tetrakisdiethylaminohafnium (Hf(Net₂)₄), tetrakis(dimethylamino)titanium (TDMAT), tertbutyliminotris(deithylamino)tantalum (TBTDET), pentakis(demethylamino)tantalum (PDMAT), pentakis(ethylmethylamino)tantalum (PEMAT), tetrakisdimethylaminozirconium (Zr(NMe₂)₄), hafniumtertiarybutoxide (Hf(tOBu)₄), xenon difluoride (XeF₂), xenon tetrafluoride (XeF₄), xenon hexafluoride (XeF₆), formations of molybdenum including, but not limited to, MoO₂Cl₂, MoO₂, MoOCl₄, MoCl₅, Mo(CO)₆, formations of tungsten including, but not limited to, WCl₅ and WCl₆, W(CO)₆, and compatible combinations and mixtures of two or more of the foregoing.

The heater 18 includes any heater capable of transferring heat via radiation. In some embodiments, the transfer of heat via radiation can include any heater capable of emitting thermal energy in the form of infrared waves. In some embodiments, the heater 18 is a directional radiant heat source. In such embodiments, the heater 18 is configured to direct radiant heating to a greater extent than the source reagent 16 is vaporized by conductive heating. In some embodiments, the heater 18 can include a light source. In some embodiments, the light source can be a light bulb. In some embodiments, the heater 18 can be selected to correspond to a specific source reagent 16. For example, in some embodiments, the source reagent 16 may be heated more efficiently by radiant energy having a particular wavelength (i.e., a wavelength sufficient to vaporize the at least one source reagent 16). In such embodiments, the heater 18 can be selected to provide the particular wavelength corresponding to the source reagent 16.

In some embodiments, the heater 18 can be capable of providing thermal energy at more than one wavelength. For example, the heater 18 can have a plurality of heat settings via which the thermal energy is provided at a particular wavelength that is suited to the source reagent 16. In some embodiments, the particular wavelength can be selected based on the type or amount of the source reagent 16 in the interior volume 14.

A heater 20 can be in thermal communication with the vaporizer assembly 10, in some embodiments. In such embodiments, the heater 20 can heat the vaporizer vessel 12 and can be conducted in any suitable manner. In one embodiment, a ribbon heater is wound around the vaporizer vessel 12. In another embodiment, a block heater having a shape covering at least a major portion of the external surface of the vaporizer vessel 12 is employed to heat the vaporizer vessel 12. In still another embodiment, a heat transfer fluid at elevated temperature may be contacted with the exterior surface of the vaporizer vessel 12, to effect heating thereof. A further embodiment involves heating by infrared or other radiant energy being impinged on the vaporizer vessel 12.

The method of heating of the vaporizer vessel 12 with heater 20 is not particularly limited as long as the vaporizer vessel 12 is brought thereby to a desired temperature level and maintained at such temperature level in an accurate and reliable manner.

FIG. 2 is a schematic diagram of a vaporizer assembly 50, according to some embodiments. Features of the vaporizer assembly 50 can be the same as or similar to features of the vaporizer assembly 10 of FIG. 1. In general, the vaporizer assembly 50 can additionally include a transparent viewport 52. In the vaporizer assembly 50, the heater 18 can be disposed outside the vaporizer vessel 12 and configured to heat the source reagent 16 through the transparent viewport 52.

In some embodiments, the vaporizer assembly 50 can be retrofit with the heater 18 since the heater 18 is disposed outside the vaporizer vessel 12. In some embodiments, the transparent viewport 52 can retain some heat, reducing an efficiency of the vaporizer assembly 50 compared to the vaporizer assembly 10. However, the heat lost may be negligible. In some embodiments, the transparent viewport 52 can be made of materials such as, but not limited to, zinc selenide, potassium bromide, Quartz (SiO₂), suitable combinations thereof, or the like.

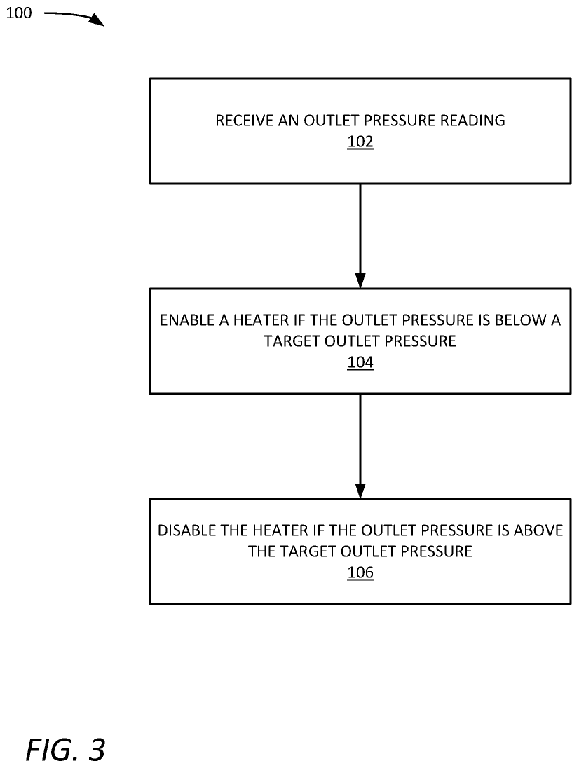

FIG. 3 is a flowchart of a method 100 for controlling a vaporizer assembly, according to some embodiments. The method 100 can be applied to the vaporizer assembly 10 of FIG. 1 or the vaporizer assembly 50 of FIG. 2.

At block 102, a controller for a vaporizer assembly (e.g., the vaporizer assembly 10 of FIG. 1 or the vaporizer assembly 50 of FIG. 2) can receive an outlet pressure reading from a pressure sensor (e.g., disposed at or near an outlet of the vaporizer assembly 10 or the vaporizer assembly 50).

At block 104, if the outlet pressure is lower than a target outlet pressure, the controller can enable a heater (e.g., the heater 18) to increase a temperature of the source reagent (e.g., the source reagent 16).

At block 106, if the outlet pressure is higher than the target outlet pressure, the controller can disable the heater to decrease the temperature of the source reagent. As discussed above, because of the heater (e.g., the heater 18) directly heating the source reagent (e.g., the source reagent 16), a response time can be decreased compared to conductive heating systems because the heat source is directly heating the source reagent instead of a thermally conductive structure.

Testing was conducted with a vaporizer vessel filled with precursor and equipped with 100-Watt and 200-Watt radiant heat source. The radiant heat source had a direct line of sight to the precursor. The flow rate of precursor from the vaporizer vessel was monitored. The vaporizer vessel was heated using external heating which produced a flow of precursor. When the radiant heat source was on, the flow rate of precursor increased at a rate greater than the baseline without the radiant heat source. When the radiant heat source was turned off, the rate of flow increase slowed.

The terminology used herein is intended to describe embodiments and is not intended to be limiting. The terms “a,” “an,” and “the” include the plural forms as well, unless clearly indicated otherwise. The terms “comprises” and/or “comprising,” when used in this Specification, specify the presence of the stated features, integers, steps, operations, elements, and/or components, but do not preclude the presence or addition of one or more other features, integers, steps, operations, elements, and/or components.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

1. An assembly, comprising:
a vaporizer vessel,
wherein the vaporizer vessel includes an interior volume,
wherein the vaporizer vessel holds at least one source reagent; and
a heater disposed within the interior volume of the vaporizer vessel,
wherein the heater is disposed within the interior volume of the vaporizer vessel in an arrangement such that the at least one source reagent is vaporized by direct heating.

2. The assembly of claim 1, wherein the heater is a radiant heat source.

3. The assembly of claim 2, wherein the heater is configured to provide radiant energy to the interior volume of the vaporizer vessel at a wavelength sufficient to vaporize the at least one source reagent.

4. The assembly of claim 2, wherein radiant energy from the heater is directed to the at least one source reagent, without passing through a solid medium, to vaporize the at least one source reagent.

5. The assembly of claim 1, further comprising a second heater configured to heat the vaporizer vessel, wherein the second heater is disposed outside the vaporizer vessel.

6. An assembly, comprising:
a vaporizer vessel,
wherein the vaporizer vessel includes an interior volume;
wherein the vaporizer vessel includes a transparent viewport;
wherein the vaporizer vessel holds at least one source reagent; and
a heater disposed outside the vaporizer vessel,
wherein the heater is disposed outside the vaporizer vessel in an arrangement such that the at least one source reagent is vaporized by heating the at least one source reagent through the transparent viewport.

7. The assembly of claim 6, wherein the heater is a radiant heat source.

8. The assembly of claim 7, wherein the heater is configured to provide radiant energy to the interior volume of the vaporizer vessel at a wavelength sufficient to vaporize the at least one source reagent.

9. The assembly of claim 7, wherein radiant energy from the heater is directed to the at least one source reagent, by passing through the transparent viewport, to vaporize the at least one source reagent.

10. The assembly of claim 6, further comprising a second heater configured to heat the vaporizer vessel, wherein the second heater is disposed outside the vaporizer vessel.

11. An assembly, comprising:
a vaporizer vessel,
wherein the vaporizer vessel includes an interior volume;
wherein the vaporizer vessel holds at least one source reagent;
a heater; and
wherein the heater is a directional radiant heat source configured to vaporize the at least one source reagent by direct radiant heating to a greater extent than the at least one source reagent is vaporized by conductive heating;
wherein the heater is configured to vaporize the at least one source reagent without heating the vaporizer vessel.

12. The assembly of claim 11, wherein the directional radiant heat source directly heats the at least one source reagent.

13. The assembly of claim 11, wherein the heater is disposed within the interior volume of the vaporizer vessel.

14. The assembly of claim 13, wherein radiant energy from the heater is directed to the at least one source reagent, without passing through a solid medium, to vaporize the at least one source reagent.

15. The assembly of claim 11, further comprising a transparent viewport.

16. The assembly of claim 15, wherein the heater is disposed outside the vaporizer vessel.

17. The assembly of claim 16, wherein radiant energy from the heater is directed through the transparent viewport to the at least one source reagent to vaporize the at least one source reagent.

18. The assembly of claim 11, wherein the heater is configured to provide radiant energy to the interior volume of the vaporizer vessel at a wavelength sufficient to vaporize the at least one source reagent.

19. The assembly of claim 11, further comprising a second heater, wherein the second heater is configured to heat the vaporizer vessel.

20. The assembly of claim 11, further comprising the at least one source reagent.
